(19) United States
(12) Patent Application Publication
(10) Pub. No.: US 2016/0254487 A1
(43) Pub. Date: Sep. 1, 2016

(54) Permeation barrier system for substrates and devices and method of making the same

(71) Applicants: UNIVERSAL DISPLAY CORPORATION, Ewing, NJ (US); THE TRUSTEES OF PRINCETON UNIVERSITY, Princeton, NJ (US)

(72) Inventors: Siddharth Harikrishna Mohan, Plainsboro, NJ (US); Ruiqing Ma, Morristown, NJ (US); William E. Quinn, Whitehouse Station, NJ (US); Bhadrinarayana Lalgudi Visweswaran, Princeton, NJ (US); Sigurd Wagner, Princeton, NJ (US)

(21) Appl. No.: 15/031,088

(22) PCT Filed: Oct. 24, 2014
(86) PCT No.: PCT/US2014/062130

§ 371 Date: Apr. 21, 2016

Related U.S. Application Data
(60) Provisional application No. 61/895,019, filed on Oct. 24, 2013.

(51) Int. Cl. H01L 51/52; B32B 15/04; B32B 7/02; H01L 51/00

(52) U.S. Cl. CPC H01L 51/5253; H01L 51/0094; B32B 15/04; B32B 7/02; H01L 2251/558; H01L 2251/301; H01L 2251/303; H01L 51/0034; B32B 2307/726

(57) ABSTRACT

Disclosed is a novel moisture permeation barrier system for substrates and devices and method of making the same. The permeation barrier system includes two barrier layers. The first barrier layer is disposed over the substrate or an electronic device. The second barrier layer is then disposed over the first barrier layer. This system has relatively low permeability to moisture and is flexible. It may cover particles and provide moisture protection with a relatively small width edge seal.

### CROSS-REFERENCE TO RELATED APPLICATIONS

This application claims priority to U.S. Provisional Patent Application Ser. No. 61/895,019, filed Oct. 24, 2013, the entire contents of which is incorporated herein by reference.

### PARTIES TO A JOINT RESEARCH AGREEMENT

The claimed invention was made by, on behalf of, and/or in connection with one or more of the following parties to a joint university corporation research agreement: Regents of the University of Michigan, Princeton University, University of Southern California, and the Universal Display Corporation. The agreement was in effect on and before the date the claimed invention was made, and the claimed invention was made as a result of activities undertaken within the scope of the agreement.

### FIELD OF THE INVENTION

The present invention relates to permeation barriers for devices such as organic light emitting diodes and other devices, and devices including the same.

### BACKGROUND

Opto-electronic devices that make use of organic materials are becoming increasingly desirable for a number of reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting devices (OLEDs), organic phototransistors, organic photovoltaic cells, and organic photodetectors. For OLEDs, the organic materials may have performance advantages over conventional materials. For example, the wavelength at which an organic emissive layer emits light may generally be readily tuned with appropriate dopants.

OLEDs make use of thin organic films that emit light when voltage is applied across the device. OLEDs are becoming an increasingly interesting technology for use in applications such as flat panel displays, illumination, and backlighting. Several OLED materials and configurations are described in U.S. Pat. Nos. 5,844,363, 6,303,238, and 5,707,745, which are incorporated herein by reference in their entirety.

One application for phosphorescent emissive molecules is a full color display. Industry standards for such a display call for pixels adapted to emit particular colors, referred to as “saturated” colors. In particular, these standards call for saturated red, green, and blue pixels. Color may be measured using CITE coordinates, which are well known to the art.

One example of a green emissive molecule is tris(2-phenylpyridine) iridium, denoted Ir(ppy)₃, which has the following structure:

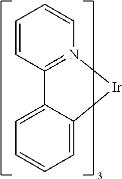

In this, and later figures herein, we depict the dative bond from nitrogen to metal (here, Ir) as a straight line.

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

More details on OLEDs, and the definitions described above, can be found in U.S. Pat. No. 7,279,704, which is incorporated herein by reference in its entirety.

### SUMMARY OF THE INVENTION

According to an embodiment, a permeation barrier is provided that includes a first barrier layer having a first water vapor permeability of not more than 10⁻⁵ g/(cm sec) and a first thickness of at least 250 nm; and a second barrier layer disposed over the first barrier layer, the second barrier layer having a second water vapor permeability and a second thickness; wherein the first water vapor permeability is higher than the second water vapor permeability. The first thickness may be greater than the second thickness and, more specifically, may be 5, 10, or up to 10⁴ times the second thickness. The permeation barrier, the first barrier layer, and/or the second barrier layer may be flexible. The first water vapor permeability may be greater than the second water vapor permeability and, more specifically, the first water vapor permeability may be at least 10, 100, or up to 10⁸ times the second water vapor permeability. The first water vapor permeability may be less than 1.3×10⁻¹¹ g/(cm·sec) or less than 3.4×10⁻¹⁴ g/(cm·sec) at 85 C, 85% RH. At least one of the first barrier layer and the second barrier layer may include one or more of silicon oxide, aluminum oxide, zinc oxide, indium oxide, tin oxide, zinc oxide, indium tin oxide, indium zinc oxide, aluminum zinc oxide, tantalum oxide, zirconium oxide, niobium oxide, molybdenum oxide and combinations thereof.

In an embodiment, a device is provided that includes a permeation barrier that includes a first barrier layer having a first water vapor permeability of not more than 10⁻⁵ g/(cm sec) at 85 C, 85% RH and a first thickness of at least 250 nm; and a second barrier layer disposed over the first barrier layer, the second barrier layer having a second water vapor permeability and a second thickness; wherein the first water vapor permeability is higher than the second water vapor permeability. The device may have a bezel of not more than 5 mm.

In an embodiment, a encapsulating an electronic device is provided, which includes depositing a first barrier layer having a first water vapor permeability of not more than 10⁻⁵ g/(cm sec) at 85 C, 85% RH and a first thickness of at least 250 nm over the electronic device; and depositing a second barrier layer over the first barrier layer, the second barrier layer having a second water vapor permeability and a second thickness; wherein the first water vapor permeability is higher than the second water vapor permeability. The first thickness may be larger than the second thickness, and the first barrier layer may be deposited at a faster rate than the second barrier layer. The first thickness may be smaller than the second thickness, and the first barrier layer may be deposited at a faster rate than the second barrier layer. The first and second barrier layers may be deposited through a common mask. The method may further include depositing a third barrier layer; depositing a fourth barrier layer over the third barrier layer; and disposing the electronic device over the third barrier layer and the fourth barrier layer; wherein the fourth barrier layer has a higher water vapor permeability than the third barrier layer; and wherein the fourth barrier layer has a greater thickness than the third barrier layer.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows a schematic cross section of a permeation barrier system according to an embodiment.

FIG. 4 shows a schematic cross section of an OLED encapsulated with a permeation barrier system with a bezel width w according to an embodiment.

FIG. 5 shows a schematic cross section of an OLED on a substrate encapsulated with a barrier layer and having a bezel width w according to an embodiment.

FIG. 6 shows a plot of the quantity of water permeated in monolayers vs. time in hours at 85 C, 85% relative humidity (RH), comparing single layer and dual layer barriers with different film solubilities according to an embodiment.

FIG. 7 shows a plot of the quantity of water permeated in monolayers vs. time in hours at 85 C, 85% RH, comparing single layer and dual layer barriers with different film solubilities according to an embodiment.

FIG. 8 shows a plot of the quantity of water permeated in monolayers vs. time in hours at 85 C, 85% RH, comparing single layer and dual layer barriers with different film diffusivities according to an embodiment.

FIG. 9 shows a plot of the quantity of water permeated in monolayers vs. time in hours at 85 C, 85% RH, comparing single layer and dual layer barriers with different film diffusivities according to an embodiment.

FIG. 10 shows a plot of the quantity of water permeated in monolayers vs. time in hours at 85 C, 85% RH, comparing single layer and dual layer barriers with different film solubilities according to an embodiment.

FIG. 11 shows a plot of the quantity of permeated water in monolayers vs. time in hours at 8 5 C, 85% RH for a barrier layer according to an embodiment.

FIG. 12 shows a plot of bezel width in m for desired permeabilities (g/cm·sec) at 85 C, 85% RH for a 1 μm thick barrier layer according to an embodiment.

FIG. 13 shows a plot of bezel width in μm for desired permeabilities (g/cm·sec) at 85 C, 85% RH for a 1 μm thick barrier layer according to an embodiment.

FIG. 14 shows a schematic cross section of an OLED on a substrate encapsulated with a permeation barrier system having a bezel width w in which the barrier system is deposited on both the top of OLED and back side of the substrate according to an embodiment.

FIG. 15 shows a schematic cross section of an OLED on a substrate encapsulated with a permeation barrier system according to an embodiment in which the barrier system is deposited on top of the substrate prior to OLED growth and a barrier system is deposited on top of OLED.

FIG. 16 shows a plot of stress change (MPa) vs. time (hours) at 85 C, 85% RH according to an embodiment.

FIG. 17 shows a photograph of a conventional OLED device at various times.

FIG. 18 shows a photograph of an OLED device as disclosed herein at various times.

FIG. 19 A shows microscopic images of a surface according to an embodiment before and after 10000 cycles of flex test.

FIG. 19 B shows microscopic images of a surface according to an embodiment before and after 10000 cycles of flex test.

### DETAILED DESCRIPTION

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75. No. 3, 4-6 (1999) (“Baldo-H”), which are incorporated by reference in their entireties. Phosphorescence is described in more detail in U.S. Pat. No. 7,279,704 at cols. 5-6, which are incorporated by reference.

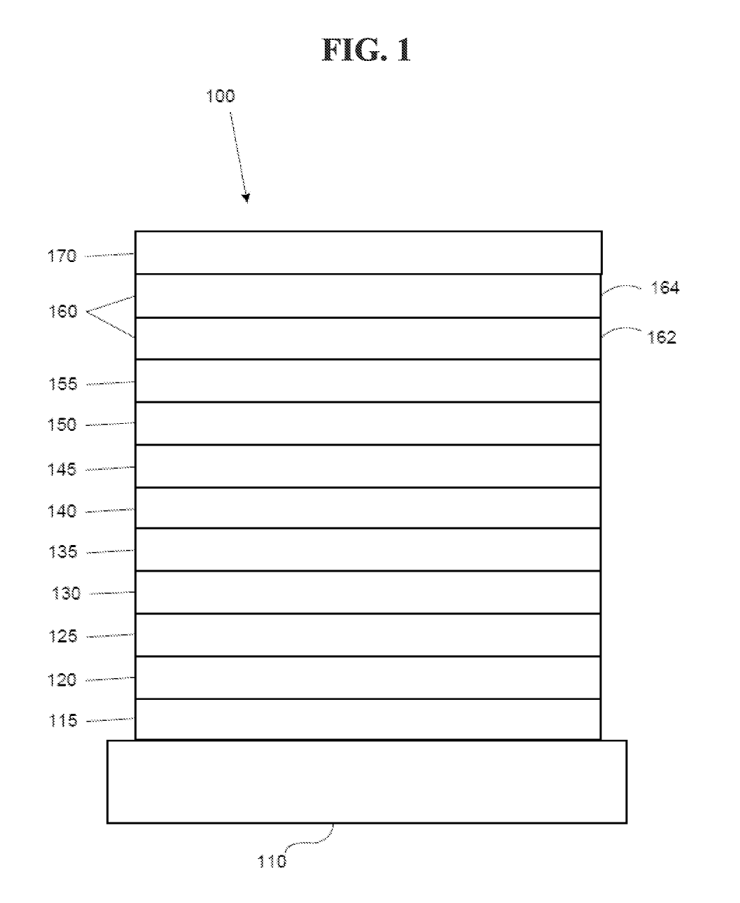

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

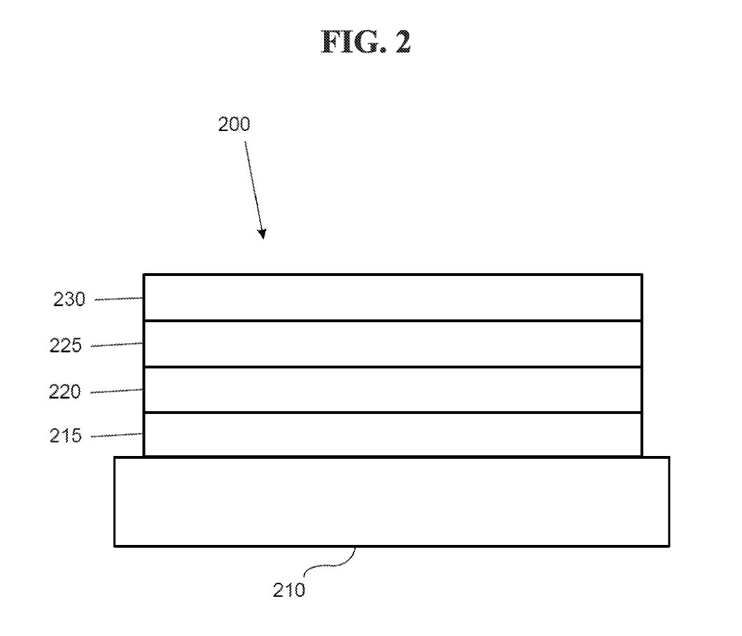

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the invention may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. A preferred barrier layer may include a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, cell phones, tablets, phablets, personal digital assistants (PDAs), laptop computers, digital cameras, camcorders, viewfinders, micro-displays, 3-D displays, vehicles, a large area wall, theater or stadium screen, or a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to +80 C.

Typically OLED displays and lighting panels need reliable protection from atmospheric gases, in particular moisture and oxygen. Many chemically-reactive, low work function metals that are used as electrodes in such devices may be unstable in the presence of these species, and can delaminate from the underlying organic layer. Similarly, commonly-used organic emitting materials may form non-emissive quenching species upon exposure to water.

In conventional OLEDs, such protection is provided by encapsulating the OLEDs and a desiccant between two glass plates, which are sealed around the edge with an adhesive. Such encapsulation techniques typically make the display rigid, and hence cannot be used for encapsulating flexible OLEDs. To make OLED displays flexible and lightweight, thin flexible barrier films are used instead of rigid glass plates. Additionally, flexible OLEDs may be fabricated on polymeric substrates such as poly ethylene terephthalate (PET), poly ethylene naphthalate (PEN), and the like, which inherently have poor moisture barrier properties. For example, the water vapor transmission rate (WVTR) of 100 μm thick PET is approximately 3.9 and 17 g/m²/day at 37.8 C and 40 C, respectively. The most widely quoted value for required water vapor transmission rate (WVTR) for an OLED lifetime of 10,000 hours is 10⁻⁶ g/m²/day. Similarly, the required oxygen transmission rate (OTR) for similar lifetimes has been reported as 10⁻⁵ cm³/m²/day to 10⁻³ cm³/m²/day.

A more direct way to specify the lifetime of OLED devices is to use the lifetime at accelerated environmental test conditions. Widely-used industrial OLED shelf lifetime specifications for different applications are 100, 500, or 1000 hours at 85 C, 85% relative humidity (RH). To ensure durable operation of OLEDs, these stringent requirements should be satisfied.

For example, when used for encapsulation of flexible OLEDs, it may be desirable for a barrier film should to be highly flexible, and to have ultra-low permeability to moisture and oxygen to meet the required OLED lifetime. In addition to the above requirements, it may be desirable for the barrier film to provide a good edge seal with a relatively small edge width requirement. At least one surface of the display should be protected with a barrier film that is substantially transparent in the visible region of the spectrum. Moreover, it is preferable that the barrier film encapsulates small particles and defects, which are potential weak spots for moisture and oxygen ingress.

Generally, the requirements of barrier films and the processes used to deposit barrier films may depend on the type of application. Specifically, it may be desirable for barrier film coatings used for encapsulating OLEDs to have the following properties:

(1) Ultralow permeability to moisture and oxygen to meet the desired OLED lifetime. As described above, the most widely-quoted value for required WVTR for an OLED lifetime of 10,000 hours is 10⁻⁶ g/m²/day. Similarly, quoted requirements for the OTR for similar lifetimes ranges between 10⁻⁵ cm³/m²/day to 10⁻³ cm³/m²/day. The permeability P of a gas such as water vapor or oxygen through a single barrier is defined as P=D·S, where S (g/cm³·atm) is the solubility of the gas in the barrier material and D is the diffusion co-efficient of the gas in the barrier material. The solubility determines how much of the permeant can be dissolved in the film, while the diffusion co-efficient determines how fast the permeant can move in the medium.

(2) Good edge seal capability. The barrier film should protect the OLED against lateral diffusion of moisture and oxygen. The film should provide a good edge seal with a relatively small edge width (bezel) requirement. Specific minimum bezel widths depend on specific applications, but typically the bezel width can range between 0.1 mm to 5 mm.

(3) Good particle coverage. It may be desirable for the barrier film to encapsulate small particles and defects, which are potential weak spots for moisture and oxygen ingress. For example, in a 300 dpi high resolution display, a particle size of 10 μm can cover about 10% of the active area of the sub pixel. Smaller particles of less than 5 μm in diameter may be generated during TFT backplane processing steps. In general, it is desirable that the barrier film thickness is least half the particle size (diameter) to completely encapsulate the particle.

Consequently, the deposition process used to manufacture a barrier film for coating OLDs should be a low temperature process so that the active components in the display are not damaged. The deposition process should have a short TACT time and be cost effective for manufacturing.

U.S. Pat. No. 6,548,912 B1. U.S. Pat. No. 6,268,695, U.S. Pat. No. 6,413,645 B1, U.S. Pat. No. 6,522,067 describe ‘multiple’ barrier stacks/dyads to encapsulate moisture sensitive devices (such as OLEDs) and substrates. Each barrier stack or a “dyad” consists of an inorganic material/polymer layer pair. The inorganic layer is the barrier layer; typically it is a metal oxide—such as polycrystalline Al₂O₃, which has low permeability for atmospheric gases. The polycrystalline Al₂O₃ is usually deposited by reactive sputtering at room temperature. These films contain microscopic defects such as pinholes, cracks, and grain boundaries that eventually form pathways for permeation of atmospheric gases including water vapor. The polymer layer is usually a polyacrylate material, which is deposited by flash evaporation of a liquid acrylate monomer that is subsequently cured by UV radiation or an electron beam. This polymer layer mechanically decouples the “defects” in the inorganic layers as disclosed in U.S. Pat. No. 6,570,325. By using multiple dyads (around 3 to 5 dyads which is 6 to 10 layers), these barrier films protect the underlying device by mechanically de-coupling the rigid inorganic layers from each other and by forcing long permeation paths on water and oxygen, so that these molecules take long times to reach the OLED. Although this method provides a long lag time for top-down diffusion of water vapor through the dyads, it fails to address the lateral/edge diffusion of water vapor. Since the polymer/decoupling layer has a high diffusion co-efficient for water vapor, a very wide edge seal is required for protection.

One way to reduce the edge seal width is disclosed in U.S. Pat. No. 7,198,832. In this method; in a given barrier stack, the area of the inorganic layer, i.e., the barrier layer is made larger than the area of the decoupling, i.e., the polymer layer. Subsequently, the area of the second barrier stack needs to be larger than the area of the first barrier stack and so on. By adopting this structure, the barrier layer can provide protection against lateral/edge diffusion of water vapor and oxygen. However, this structure fundamentally poses a limit on the minimum edge width obtainable. The ‘edge width’ or ‘bezel width’ is a non-usable portion of the display. It is almost impossible to obtain an almost zero-edge or an edgeless display. Moreover, the deposition rate of the barrier layer, i.e., the sputtered metal oxide layer increases the TACT. Additionally, the substrate needs to be translated from the sputter chamber (vacuum) to an inert atmosphere chamber (non-vacuum) to flash evaporate the monomer layer and cure it and vice versa. Multiple transfers between chambers, intervening masking steps for barrier overlap, etc., considerably increase the TACT for such techniques.

U.S. Pat. No. 7,015,640 B2 discloses the use of graded composition diffusion barrier to encapsulate OLEDs and substrates. In this method, multiple alternate layers of SiOₓN_{y}/SiOₓC_{y} are deposited at room temperature by PECVD. The composition of the layers is dependent on the reactant gases and process parameters. The SiOₓC_{y} tends to give the polymer-like effect, while the SiOₓNy is the inorganic barrier layer. Other layers such as SiC, SiNₓ, SiOₓ, AlOₓC_{y}N_{z} can be deposited by the same method. Obtaining ultralow permeability in this barrier system depends on the inorganic layer, i.e., SiOₓN_{y}. Inorganic thin films (barrier layers) such as SiOₓ, SiNₓ or SiOₓN_{y}, when deposited at room temperature, develop self-relief micro-cracks once they reach a critical thickness. The flexibility of the graded compositional diffusion barrier depends on its adhesion and the built-in stress of the inorganic layer.

Other techniques have been reported, such as in Chen et al., which disclosed multilayer barrier deposition of SiOx/SiNx stacks, in which six stacks were needed to meet OLED requirements. Graham et al. disclosed the use of SiOx/SiNx/Parlyene (3 pairs)+SiOx/SiNx (3 pairs) in “Approaches to Barrier Coatings for the Prevention of Water Vapor Ingress” (available at http://www1.eere.energy.gov/solar/pdfs/pvrw2010_graham.pdf). Obtaining ultralow permeability in this barrier system depends on the inorganic layer, i.e., SiOₓ and SiNₓ. Inorganic thin films (barrier layers) such as SiOₓ, SiNₓ or SiOₓN_{y} when deposited at room temperature develop self-relief micro-cracks once they reach a critical thickness. The flexibility of this barrier depends on the adhesion and the built-in stress of the inorganic layer.

Single layer encapsulation by Atomic Layer Deposition (ALD) was demonstrated in P. F. Carcia, R. S. McLean, M. H. Reilly, M. D. Groner, S. M. George, Applied Physics Letters, 2006, 89, 031915, which disclosed encapsulating a polymer substrate (PET) by ALD of Al₂O₃. A high density, pin hole free, conformal barrier coating was obtained with decent WVTR of 1.7×10⁻⁵ g/m²/day. The coating is dominated by nano-defects rather than micro-defects. The disadvantage of ALD process is that the process has a large TACT time and thus depositing a thick layer for particle coverage will be a challenge.

In general, single- or multi-layer inorganic thin films (barrier layers) such as SiNx or SiOx or SiOxNy, when deposited at room temperature develop self-relief micro-cracks once they reach a critical thickness. The flexibility of the graded compositional diffusion barrier will depend on the adhesion and built-in stress of the inorganic layer.

A hybrid barrier layer grown by plasma enhanced chemical vapor deposition (PECVD) of an organic precursor with a reactive gas such as oxygen, e.g., HMDSO/O₂ is described in U.S. Pat. No. 7,968,146, the disclosure of which is incorporated by reference in its entirety. The barrier film is highly impermeable yet flexible. This material is a hybrid of inorganic SiO₂ and polymeric silicone that is deposited at room temperature. The barrier film has permeation and optical properties of glass, but with a partial polymer character that gives a thin barrier film a low permeability and flexibility. At room temperature, a layer of this hybrid material is free of microcracks when deposited approximately thicker than 100 nm. The advantages of this barrier include: ultralow permeability to moisture and oxygen, particle coverage (conformal coating by PECVD), good edge seal with minimal edge/bezel requirement, transparency and flexibility. The deposition process is a cost-effective one step process with somewhat average TAC time.

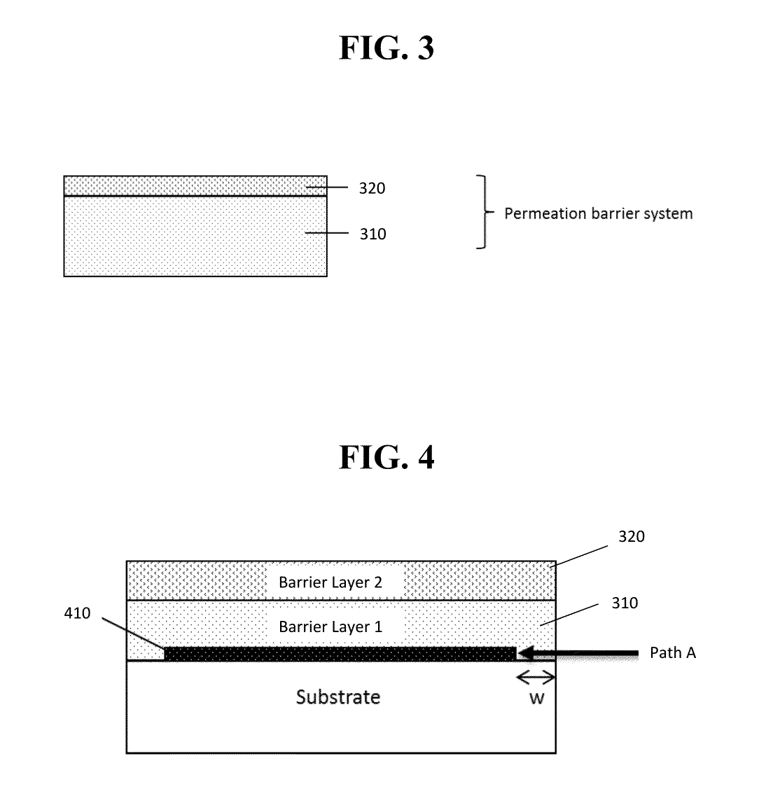

Embodiments disclosed herein provide a permeation barrier system for substrates and devices. The permeation barrier system may include two layers, as shown in FIG. 3. The first barrier layer 310 (referred to herein as Barrier layer 1) may be disposed over the substrate or over an electronic device such as an OLED. The first barrier layer 310 may have a water vapor permeability of not more than 10⁻¹⁵ g/(cm sec) at 85 C, 85% RH. As described in specific examples herein, lower permeabilities may be used in some configurations to achieve specific properties of the barrier layer, or of the system as a whole. The first barrier layer may have a thickness of at least 250 nm. Larger thicknesses may be used, as described in further detail herein. The second barrier layer 320 (referred to herein as Barrier layer 2) is then capped over the first barrier layer. FIG. 4 shows a schematic cross section of an OLED 410 encapsulated with a permeation barrier system as disclosed herein. In general, the second barrier layer 320 may have lower water vapor permeability than the first layer. The water vapor permeability of the first layer may be at least 10 times the second; more generally, it may be from 10 to 108 times the permeability of the second layer. The first layer 310 may have a water vapor permeability of, for example, less than 1.3×10⁻¹¹ g/(cm·sec) at 85 C, 85% RH, or less than 3.4×10⁻¹⁴ g/(cm·sec) at 85 C, 85% RH though, as disclosed in further detail herein, other values may be used. In general, barrier layers as disclosed herein may have water vapor permeability in the range of 10⁻¹¹ to 10⁻¹⁵ g/(cm·sec). The thickness of Barrier layer 1 may be greater than that of Barrier layer 2. For example, Barrier layer 1 may be 5, 10, or 100 times thicker than Barrier layer 2. More generally, the first barrier layer may be from 5 to 10⁴ times the thickness of the second barrier layer.

Because Barrier layer 1 310 is disposed over the OLED as shown in FIG. 4, the water vapor permeability of this layer generally will govern the edge seal of the OLED. That is, it will provide the primary mechanism for protection against the horizontal diffusion of water vapor and oxygen through the edge of the OLED, such as along Path A. Thus, it may be desirable that this layer have a relatively low permeability to meet the target shelf lifetime with minimal bezel width w requirement.

Barrier layer 1 as disclosed herein may have a low enough permeability to meet the lifetime requirement with a relatively small bezel width w. The time 1 monolayer of water molecules (one monolayer corresponds to 1×10⁻⁸ g/cm²) to reach an OLED near the bezel edge by diffusion via the 1 mm width of the barrier layer is 100 hours for a permeability of 1.9×10⁻¹² g/(cm·sec) at 85 C, 85% RH. (As the partial pressure of water at 85 C, 85% RH is 0.485 atm, the permeability is specified in g/(cm·sec)). Thus, if the acceptable bezel width is 1 mm, the permeability P1 of the barrier layer 1 310 should be less than 1.9×10⁻¹² g/(cm·sec) at 85 C, 85% relative humidity to meet 500 hours lifetime. A detailed explanation of this calculation is provided in further detail below. If the solubility S1 of water vapor in barrier layer 1 is 3 mg/cm³ at 85 C, 85% RH, then a diffusion co-efficient of water vapor D1 of 6.33×10⁻¹⁰ cm²/sec will be desired (P1=D1·S1). Similarly, minimum P1 values can be calculated based on acceptable bezel width and target shelf lifetime specifications. In general, embodiments disclosed herein allow for bezel widths of 5 mm or less.

As previously described, small particles and defects may be potential weak spots for moisture and oxygen ingress. Thus, it may be desirable for particles and defects to be covered with the barrier layer for effective encapsulation. This suggests that Barrier layer 1 should be relatively thick. For example, if a 10 μm particle needs to be effectively encapsulated, a minimum barrier thickness of 5 μm is desired. Similarly, in a particle controlled environment, if the maximum size of the particle is 5 μm, the thickness of Barrier layer 1 may be chosen to be greater than 2.5 μm.

It also may be desirable for Barrier layer 1 to be deposited with a relatively short total average cycle time (TACT) for feasible manufacturability. Since a relatively low permeability is expected to sufficient for an edge seal, ultralow permeability may not be required, thus potentially providing a relatively large process window.

Thus, Barrier layer 1 may be chosen to provide a desired edge seal with a minimal bezel width, to provide particle coverage, and to be fabricated via a deposition process having a short total average cycle time.

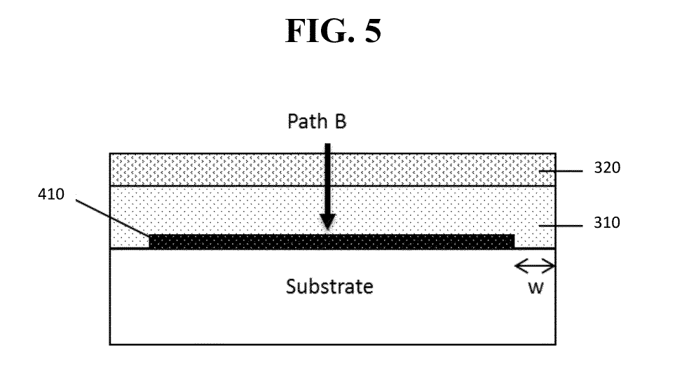

To address the desirability of a barrier having ultralow permeability for water vapor and oxygen a Barrier layer 2 as disclosed herein, which may have relatively low permeability to moisture and oxygen, may be deposited over the Barrier layer 1. Notably, the permeability of water vapor through barrier layer 2 (P2) may be smaller than the permeability of water vapor through barrier layer 1 (P1). FIG. 5 shows a schematic cross section of an OLED encapsulated with a permeation barrier system as disclosed herein. In FIG. 5, path B represents a vertical water vapor diffusion path. Barrier layer 2 may be chosen to have superior permeation barrier properties, so that even a relatively thin layer can provide effective protection. If Barrier layer 2 320 and Barrier layer 1 310 have the same diffusion co-efficients of water vapor (D2=D1), then the solubility of water vapor in Barrier layer 2 is less than that of the barrier layer 1 (S2<S1). On the other hand, if the solubilities are the same (S1=S2), then the diffusion co-efficient D2 is less than D1.

In addition to the above criteria, it may be preferable that both barrier layers are flexible. Barrier layer 1 310 is considered ‘flexible’ if a 1 micron thick layer passes 10,000 cycles of a rolling test over a 0.5-inch radius without any cracks or delamination. Similarly. Barrier layer 2 320 is considered ‘flexible’ if a 50 nm thick layer passes 10,000 cycles of a rolling test over a 0.5-inch radius without any cracks or delamination.

Thus, as shown in further detail below, a permeation barrier system that includes both barrier layers as disclosed herein may meet several the following functional requirements, including an ultralow permeability to moisture and oxygen, good edge seal with minimal bezel width, particle coverage, short TACT, and flexibility.

In order to provide effective encapsulation, the rate of ingress of water vapor through the barrier system in the vertical direction (along Path B in FIG. 5) should be minimal. Water permeates through the barrier by diffusion. The concentration of dissolved water in the barrier and permeated water can be determined by solving Fick's laws of diffusion which, for one dimension, are given by

$$\frac{d C}{d t} = D \frac{{d}^{2} C}{d {x}^{2}}$$

$$J = - D \frac{d C}{d X}$$

where C is the concentration of dissolved water, D is the diffusion coefficient, x is the distance from the surface into a layer, t is the elapsed time, and J is the diffusive flux.

When a device is held in a standard testing condition, the following are the boundary conditions:

1. The barrier surface is exposed to the environment with a constant chemical potential of water, and hence the surface concentration of dissolved water C₀ is determined only by test temperature and humidity.

2. The barrier surface on the OLED side has zero concentration of water as the OLED absorbs all water that reaches it.

By solving the diffusion equations for these boundary conditions, the quantity of all water that has permeated a barrier made of a single material after time t of exposure to humidity at a fixed temperature is given by the expression

$$Q ( t ) = \frac{{DtC}_{0}}{H} - \frac{{HC}_{0}}{6} - \frac{2 {HC}_{0}}{{π}^{2}} {\sum }_{n = 1}^{∞} \frac{{( - 1 )}^{n}}{{n}^{2}} {e}^{- {Dn}^{2} {π}^{2} t / {H}^{2}}$$

where Q(t) is the quantity of water that has permeated through a film of thickness H in time t, D is the diffusion coefficient, C₀ is the surface concentration of water, and H is the barrier thickness.

Because OLEDs are highly sensitive to chemical attack by water, a realistic but very demanding requirement is that during the entire lifetime of the protected OLED less than one monolayer of water molecules permeate through the barrier into the OLED. The lifetime τ_{1ML} so defined can be predicted if the thickness of the barrier H, and the concentration of water molecules at the surface of the barrier C(x=0)=C₀ and the coefficient of diffusion D of water molecules in the barrier are known.

The diffusion coefficient for Barrier layer 1 and Barrier layer 2 as disclosed herein are D1 and D2 respectively. The solubility for Barrier layer 1 and Barrier layer 2 as disclosed herein are S1 and S2, respectively. In a system as disclosed herein, Barrier layer 2 may be chosen such that the permeability of water vapor through Barrier layer 2 (P2) is less than the permeability of water vapor through barrier layer 1 (P1). This layer provides the ultimate barrier against vertical diffusion (Path B in FIG. 5) of water vapor.

P2<P1 can be understood in 3 different cases:

Case A: If the Barrier layer 2 and Barrier layer 1 have the same solubility of water vapor (S2=S1), then the diffusion co-efficient of Barrier layer 2 is less than that of the Barrier layer 1 (D2<D1).

Case B: If the diffusion co-efficients are the same (D1=D2), then the solubility is S2<S1.

Case C: D2<D1 and S2<S1.

To determine the importance of having an ultralow permeability for Barrier layer 2, numerical simulations were performed to estimate the amount of water permeated in the vertical direction (Path B in FIG. 5) for these three cases. The most stringent shelf lifetime requirement of 1000 hours at 85 C, 85% RH is used as the target for all simulations.

In the simulation of Case A (D2<D1 when S1=S2), the diffusion coefficient of Barrier layer 1 is varied, D1=10⁻¹⁰ cm²/sec. 10⁻¹² cm²/sec, 10⁻¹⁴ cm²/sec. The diffusion co-efficient of Barrier layer 2, D2 is fixed at D2=10⁻¹⁶ cm²/sec. All the diffusion coefficients and solubilities used for calculations are for 85 C, 85% RH. Reference is a 1 μm single Barrier layer 1. In the examples according to embodiments disclosed herein, the thickness of Barrier layer 1 is 950 nm and Barrier layer 2 is 50 nm.

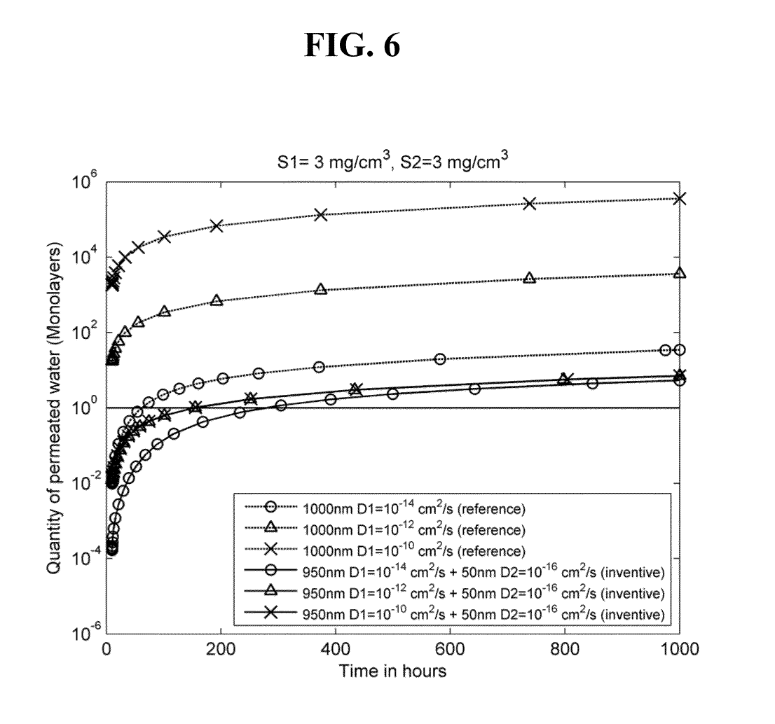

FIG. 6 shows a plot of the quantity of water permeated in monolayers vs. time in hours, at 85 C, 85% RH. As seen from the plot, for a 1000 nm single barrier layer with D1=10⁻¹⁴ cm²/sec (Reference), 1 monolayer of water (horizontal line intercept) permeates through the barrier and reaches the device to be protected in 62 hours. In a permeation barrier system as disclosed herein (950 nm of barrier layer 1 having D1=10⁻¹⁴ cm²/sec+50 nm barrier layer 2 with D2=10⁻¹⁶ cm²/sec), the time taken for 1 monolayer to reach the OLED is about 280 hours. (The partial pressure of water at 85 C, 85% RH is 0.485 atm. Here and throughout the present disclosure, the units of solubility and permeability are specified in mg/cm³ and g/(cm·sec) as the model accounts for the partial pressure change.)

For a higher diffusion co-efficient, 1000 nm of D1=10⁻¹² cm²/sec and 1000 nm of D1=10⁻¹⁰ cm²/sec, the characteristic diffusion length is large and water permeates rapidly if a single layer barrier structure is adopted. The time taken for one monolayer of water to reach the surface in the above two cases is 0.7 hours and 22 seconds, respectively. However, in a permeation barrier system as disclosed herein ((950 nm of D1=10⁻¹² cm²/sec+50 nm D2=10⁻¹⁶ cm²/sec) and (950 nm of D1=10⁻¹⁰ cm²/sec+50 nm D2=10⁻¹⁶ cm²/sec)), the time taken for one monolayer to reach the surface is 154 hours and 153 hours, respectively. This suggests that the ultralow permeability is predominantly governed by the ultra-low diffusion coefficient of Barrier layer 2 when D1 is large. This also indicates that ultralow permeability is not a hard requisite for the Barrier layer 1, as long as it has sufficient permeation barrier properties to provide a relatively high edge seal and particle coverage.

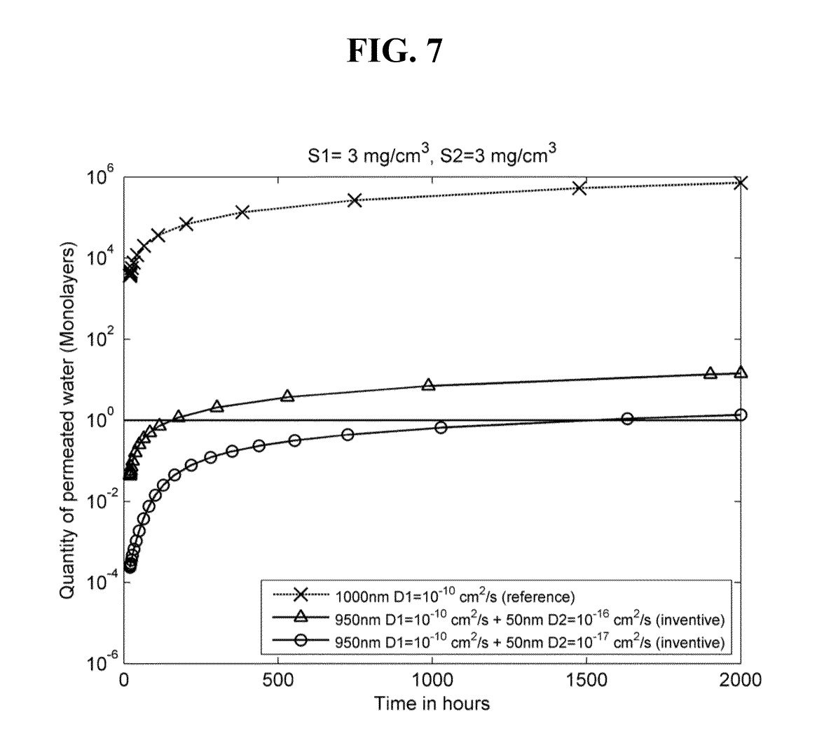

Presuming an acceptable bezel width is 1 mm and a target shelf life time is 1000 hours in 85 C, 85% RH, evaluation of the edge seal performance indicates that any Barrier layer 1 with a diffusion coefficient D1 of not more than 1×10⁻¹⁰ cm²/sec can provide a good edge seal. However, a single barrier layer with D1=10⁻¹⁰ cm²/sec does not provide adequate protection in the vertical direction. If, for example, Barrier layer 2 is an inorganic layer, it is possible to obtain a lower diffusion coefficient when this layer is free of defects, cracks and grain boundaries. However, it may be desirable for this layer to be thin, so as to not compromise on flexibility. In this case, it is possible to calculate the shelf lifetime if 950 nm D1=10⁻¹⁰ cm²/sec (S1=3 mg/cm³) is capped with 50 nm of diffusion co-efficient D2=10⁻¹⁶ cm²/sec, D2=10⁻¹⁷ cm²/sec. FIG. 7 shows a plot of the quantity of water permeated vs. time for such a system at 85 C, 85% RH. As can be seen from the plot, for a 1000 nm single barrier layer with D1=10⁻¹⁰ cm²/sec (Reference), 1 monolayer of water permeates through the barrier and reaches the surface to be protected in 22 seconds. In a permeation barrier system according to an embodiment herein (950 nm of barrier layer 1 having D1=10⁻¹⁰ cm²/sec+50 nm barrier layer 2 with D2=10⁻¹⁶ cm²/sec), the time taken for 1 monolayer to reach the protected surface is about 153 hours. For a system including 950 nm of barrier layer 1 having D1=10⁻¹⁰ cm²/sec and 50 nm barrier layer 2 with D2=10⁻¹⁷ cm²/sec, the time taken for 1 monolayer to reach the protected surface is 1524 hours, which surpasses the target shelf lifetime.

These results indicate that Barrier layer 1 as disclosed herein governs the edge seal phenomenon, while Barrier layer 2 provides protection in the vertical direction.

For the simulation of Case B (S2<S1 when D2=D1), the diffusion co-efficient of Barrier layer 1 and Barrier layer 2 are fixed at D1=D2=10⁻¹⁴ cm²/sec and the solubility of Barrier layer S2 is varied from 3 mg/cm³ to 0.03 mg/cm³. All the diffusion coefficients and solubilities are for 85 C, 85% RH. The reference layer is a 1 μm single Barrier layer 1. In the examples according to embodiments disclosed herein, the thickness of Barrier layer 1 is 950 nm and Barrier layer 2 is 50 nm.

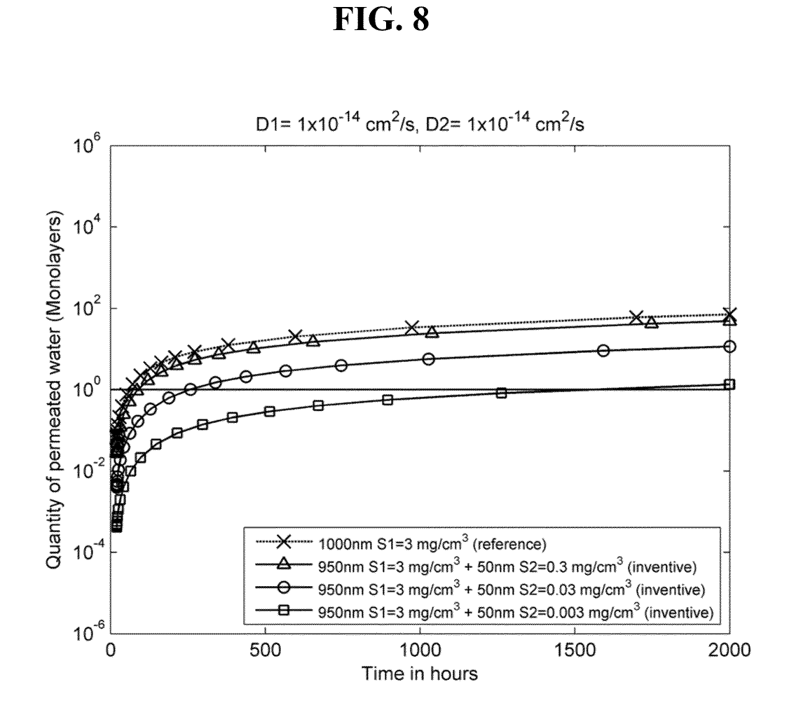

FIG. 8 shows a plot of the quantity of water permeated vs. time at 85 C, 85% RH. As seen from the plot, for a 1000 nm single barrier layer with D1=10⁻¹⁴ cm²/sec, S1=3 mg/cm³ (Reference), 1 monolayer of water permeates through the barrier and reaches the device to be protected in 62 hours. In the permeation barrier system as disclosed herein (950 nm of barrier layer 1 having D1=10⁻¹⁴ cm²/sec, S1=3 mg/cm³+50 nm barrier layer 2 with D2=10⁻¹⁴ cm²/sec, S2=0.3 mg/cm³), the time taken for 1 monolayer to reach the surface is about 94 hours. For even lower S2 values (S2=0.03 mg/cm³ and S2=0.003 mg/cm³, the time taken is 264 hours and 1558 hours respectively. This suggests that the ultralow permeability is predominantly governed by the ultra-low solubility of Barrier layer 2. This data also suggests that ultralow permeability is not a hard requisite for Barrier layer 1 as long as it has sufficient permeation barrier properties to provide the required edge seal and particle coverage.

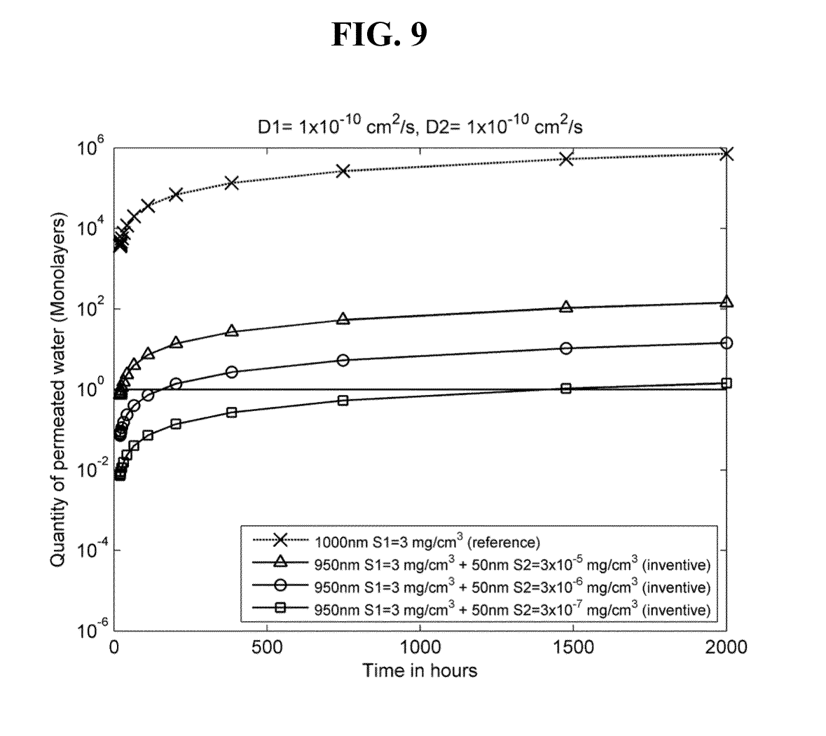

Similar to Case A, an acceptable permeation barrier system as disclosed herein may be designed with a Barrier layer 1 which has a diffusion co-efficient D1=1×10⁻¹⁰ cm²/sec (again presuming a bezel width of 1 mm and a target shelf life time of 1000 hours in 85 C, 85% RH). In this case, it is possible to calculate the shelf lifetime if 950 nm D=10⁻¹⁰ cm²/sec (S1=3 mg/cm³) is capped with 50 nm of diffusion co-efficient D2=10⁻¹⁰ cm²/sec, by varying the solubility S2. FIG. 9 shows a plot of the quantity of water permeated vs. time at 85 C, 85% RH for such a system. As seen from the plot, for a 1000 nm single barrier layer with D1=10⁻¹⁰ cm²/sec and S1=3 mg/cm³ (Reference), 1 monolayer of water permeates through the barrier and reaches the surface to be protected (e.g., an OLED) in 22 seconds. In a permeation barrier system according to an embodiment (950 nm of barrier layer 1 having D1=10⁻¹⁰ cm²/sec+50 nm barrier layer 2 with D2=10⁻¹⁰ cm²/sec, S2=3×10⁻⁵ mg/cm³), the time taken for 1 monolayer to reach the OLED is about 19 hours. For S2=3×10⁻⁶ mg/cm³ and 3×10⁻⁷ mg/cm³, time taken for 1 monolayer to reach the OLED is 151 hours and 1420 hours respectively. This indicates that Barrier layer 1 governs the edge seal phenomenon while Barrier layer 2 provides protection in the vertical direction.

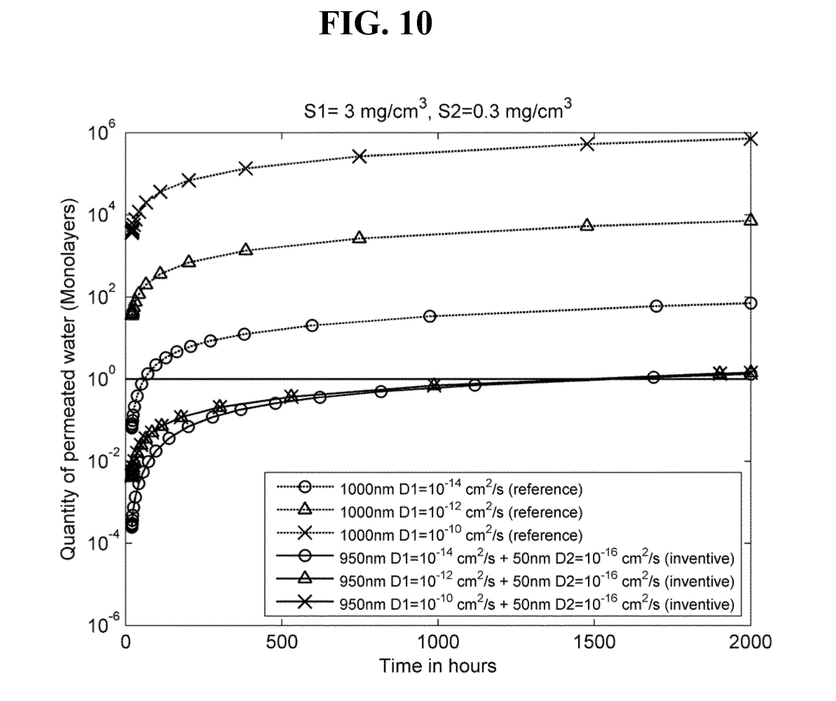

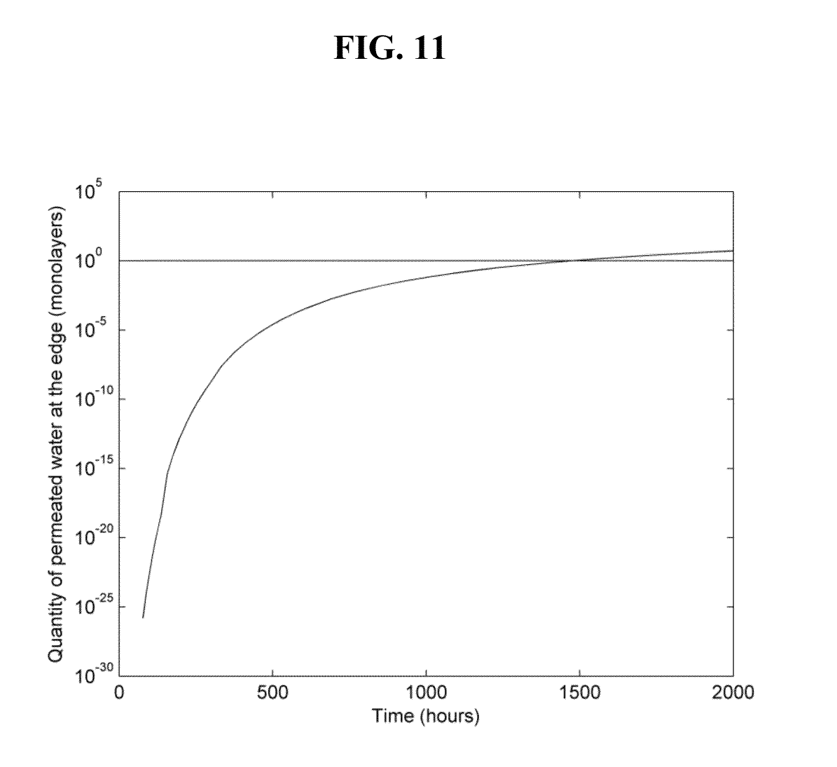

In the simulation of Case C (D2<D1 and S2<S1, the diffusion co-efficient of barrier layer 1 is varied, D1=10⁻¹⁰ cm²/sec, 10⁻¹² cm²/sec, 10¹⁴ cm²/sec. The diffusion co-efficient of barrier layer 2. D2 is fixed at D2=10⁻¹⁶ cm²/sec. The solubility S2 is fixed at 0.3 mg/cm³ (one tenth−S1). All the diffusion co-efficients and solubilities are for 85 C, 85% RH. The total thickness of barrier system is fixed at 1000 nm (1 um) i.e: Reference is a 1000 nm (1 um) thick single barrier layer 1. In the inventive examples, the thickness of barrier layer 1 is 950 nm and barrier layer 2 is 50 nm. FIG. 10 shows a plot of the quantity of water permeated vs. time at 85 C, 850% RH. As seen from the plot, for a 1000 nm single barrier layer with D1=10⁻¹⁴ cm²/sec (Reference), 1 monolayer of water permeates through the barrier and reaches the surface to be protected in 62 hours. In the structure according to an embodiment disclosed herein (950 nm of D1=10⁻¹⁴ cm²/sec+50 nm D2=10⁻⁻¹⁶ cm²/sec), the time taken for 1 monolayer to reach the surface is more than 1000 hours. For a higher diffusion co-efficient (1000 nm of D1=10⁻¹² cm²/sec and 1000 nm of D1=10⁻¹⁰ cm²/sec), the characteristic diffusion length is relatively large and water permeates rapidly if a single layer barrier structure is adopted—the time for one monolayer of water to reach the surface is 0.7 hours and 22 seconds, respectively. However, in structures according to an embodiment disclosed herein (950 nm of D1=10⁻¹² cm²/sec+50 nm D2=10⁻¹⁶ cm²/sec, S2=0.3 mg/cm³·atm) and (950 nm of D1=10⁻¹⁰ cm²/sec+50 nm D2=10⁻¹⁶ cm²/sec, S2=0.3 mg/cm³·atm), the times taken for one monolayer to reach the surface are 1406 hours, 1407 hours and 1544 hours respectively. This ultralow permeability is solely governed by the low solubility and diffusion co-efficient of Barrier layer 2.

All of Cases A-C above demonstrate the effect of an ultralow permeability Barrier layer 2 in embodiment disclosed herein. The ultralow permeability of Barrier layer 2 primarily governs the ‘permeation barrier’ feature of such a system. This also indirectly suggests that ultralow permeability is not a hard requisite for Barrier layer 1 as long as it has sufficient permeation barrier property to provide the required edge seal and particle coverage.

As previously described, embodiments disclosed herein may allow for coverage of particles and defects, which are potential weak spots for moisture and oxygen ingress. For example, in a 300 dpi high resolution display, a particle size of 10 μm can cover about 10% of the active area of the sub pixel. Even smaller particles of less than 5 μm diameter may be generated during TFT backplane processing steps. For example, if Barrier layer 1 is deposited by PECVD, conformable coating of the substrate, including roughness, profiles, and particles can be obtained. The thickness of Barrier layer 1 is chosen based on the maximum particle size that needs to be effectively encapsulated. For example, if a 10 μm particle needs to be effectively encapsulated, a minimum barrier thickness of 5 μm may be desired. Similarly, in a particle controlled environment, if the maximum size of the particle is 5 μm, the thickness of Barrier layer 1 may be chosen to be 2.5 μm. In such a configuration, Barrier layer 2 deposited over barrier layer 1 may provide ultimate protection from water permeation. The thickness of Barrier layer 1 may primarily governs the ‘particle coverage’ feature of a permeation barrier system as disclosed herein.

In an embodiment, a permeation barrier system as disclosed herein may provide an acceptable edge seal with minimal bezel requirement. As previously described, Barrier layer 1 may be disposed over the OLED with a bezel width w, i.e., the footprint of Barrier layer 1 extends beyond the edge of the OLED display by a distance w, as shown in FIGS. 3-5. To provide an acceptable edge seal, the rate of ingress of water vapor in the horizontal direction (along Path A in FIG. 4) should be considered.

The flux of water molecules diffusing is proportional to the bulk diffusion coefficient D1 of water in the barrier layer, neglecting interfacial effects. As previously described, a realistic but very demanding requirement is that during the entire lifetime of the protected OLED one monolayer of water molecules reaches the surface of the OLED near the edge. For a given diffusion coefficient D1, solubility S1, and bezel width w, it is possible to calculate the quantity of permeated water reaching the edge of the OLED by solving Fick's second law of diffusion as it applied to 2 or 3 dimensional systems:

$$\frac{\partial C}{\partial t} = D {∇}^{2} C$$

where, as before, C is the concentration of dissolved water, D is the diffusion coefficient, and t is the elapsed time.

A solution may obtained by solving the equation with a finite element method, for example using COMSOL and MATLAB, for the following boundary conditions:

1. The edge surface of Barrier layer 1 exposed to the environment has a constant concentration of dissolved water equal to solubility S1 determined by test temperature and humidity.

2. Barrier layer 1 disposed over the OLED has zero water concentration as the OLED absorbs the water.

The simulation results for different barrier properties are shown in FIGS. 11-13. FIG. 11 shows a plot of the quantity of permeated water vs. time at 85 C, 85% RH for D1=1×10⁻¹² cm²/sec, S1=3 mg/cm³ (P1=3×10⁻¹⁵ g/cm·sec) and w=100 μm, for a thickness of Barrier layer 1 of 1 μm. As seen, 1 monolayer of water reaches the OLED edge in approximately 1463 hours. Thus, if the target shelf lifetime is 1000 hours at 85 C, 85% RH, a bezel width as small as 100 μm can provide an acceptable edge seal. All of the above simulations are done assuming S1=3 mg/cm³ and barrier layer 1 thickness of 1 um and reported P1 and D1, S1 values are at 85 C, 85% RH.

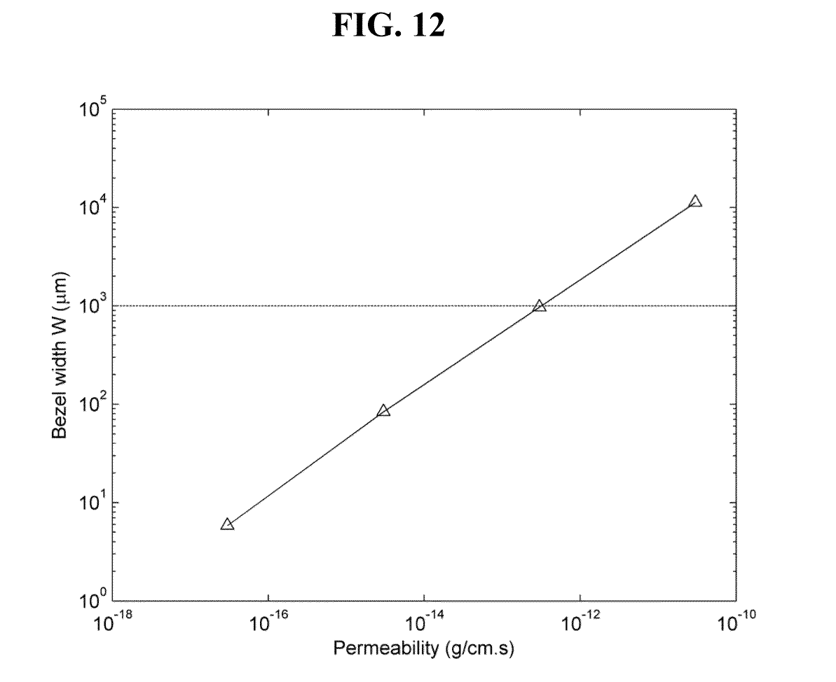

It is possible to simulate a minimum required bezel width as a function of the permeability to meet the condition that 1 monolayer of water diffuses in 1000 hours at 85 C, 85% RH. FIG. 12 shows a plot of the required bezel width as a function of the permeability (g/cm·sec) at 85 C, 85% RH to meet the condition that 1 monolayer of water diffuses in 1000 hours, assuming S1=3 mg/cm³. As seen for a relatively very low P1=3×10⁻¹⁷ cm²/sec (D1=1×10⁻¹⁴ cm²/sec), a bezel width as small as 6 μm can provide a good edge seal. For P1=3×10⁻¹⁵ cm²/sec (D1=1×10⁻¹² cm²/sec), a bezel width as small as 84 μm is sufficient. As the permeability value increases, a wider bezel may be required. At P1=3×10⁻¹³ cm²/sec, (D1=1×10⁻¹⁰ cm²/sec), a bezel width of 972 μm is required. For an even higher P1 of 3×10⁻¹¹ cm²/sec (D1=1×10⁻⁸ cm²/sec), a bezel width of almost 11.2 mm is required. All of the above simulations are done assuming S1=3 mg/cm³ and barrier layer 1 thickness of 1 um and reported P1 and D1, S1 values are at 85 C, 85% RH

Table 1 provides the minimum required permeability of Barrier layer 1 for a given bezel width to meet 1000 hours at 85 C, 85% RH under this model:

TABLE 1

| | Minimum required |
|---|---|
| Bezel Width | permeability at 85 C., 85% |
| (mm) | RH (g/cm · sec) |
| 0.1 | 4.8 × 10⁻¹⁵ |
| 0.5 | 9.2 × 10⁻¹⁴ |
| 1 | 3.3 × 10⁻¹³ |
| 2 | 1.2 × 10⁻¹² |
| 3 | 2.5 × 10⁻¹² |
| 4 | 4.2 × 10⁻¹² |
| 5 | 6.3 × 10⁻¹² |

Similar calculations can be made for other shelf life. Table 2 provides the minimum required permeability of barrier layer 1 for a given bezel width to meet 500 hours at 85 C, 85% RH:

TABLE 2

| | Minimum required |
|---|---|
| Bezel Width | permeability at 85 C., 85% |
| (mm) | RH (g/cm · sec) |
| 0.1 | 9.0 × 10⁻¹⁵ |
| 0.5 | 1.7 × 10⁻¹³ |
| 1 | 5.8 × 10⁻¹³ |
| 2 | 2.0 × 10⁻¹² |
| 3 | 4.2 × 10⁻¹² |
| 4 | 7.1 × 10⁻¹² |
| 5 | 1.1 × 10⁻¹¹ |

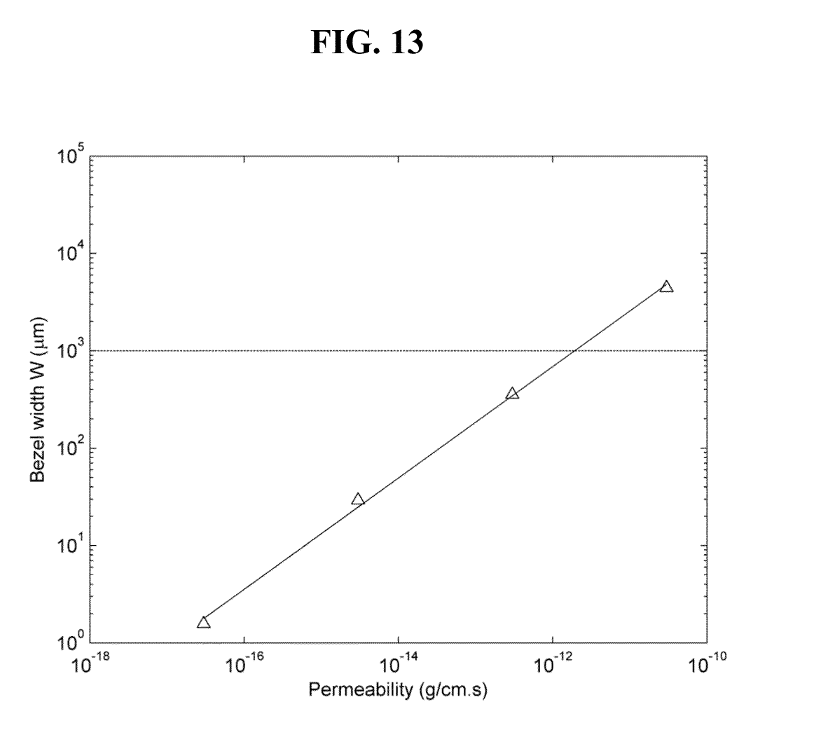

For applications with less stringent requirements, such as a shelf lifetime of 100 hours at 85 C, 85% RH, FIG. 13 shows a plot of the required bezel width vs. permeability at 85 C, 85% RH, to meet the condition that 1 monolayer of water diffuses in 100 hours, presuming S1=3 mg/cm³.

As seen for a very low P1=3×10⁻¹⁷ cm²/sec (D1=1×10⁻¹⁴ cm²/sec), a bezel width as small as 1.6 μm can provide a good edge seal. For P1=3×10⁻¹⁵ cm²/sec (D1=1×10⁻¹² cm²/sec), a bezel width as small as 30 μm is sufficient. As the permeability value increases, a wider bezel is required. At P1=3×10⁻¹³ cm²/sec, (D1=1×10⁻¹⁰ cm²/sec), a bezel width of 360 μm may be required. For an even higher P1 of 3×10¹¹ cm²/sec (D1=1×10⁻¹¹ cm²/sec), a bezel width of almost 4.5 mm is required. All of the above simulations assume S1=3 mg/cm³ and barrier layer 1 thickness of 1 um and reported P1 and D1, S1 values are at 85 C, 85% RH.

Table 3 provides the minimum required permeability of barrier layer 1 for a given bezel width to meet 100 hours at 85 C, 85% RH.

TABLE 3

| | Minimum required |
|---|---|
| Bezel Width | permeability at 85 C., 85% |
| (mm) | RH (g/cm · sec) |
| 0.1 | 3.4 × 10⁻¹⁴ |
| 0.5 | 5.7 × 10⁻¹³ |
| 1 | 1.9 × 10⁻¹² |
| 2 | 6.5 × 10⁻¹² |
| 3 | 1.3 × 10⁻¹¹ |
| 4 | 2.2 × 10⁻¹¹ |
| 5 | 3.2 × 10⁻¹¹ |

Note:
The 1 monolayer time shows a weak dependence on the thickness of the barrier ‘h1’ when h1 << w.

As previously disclosed, in an embodiment a permeation barrier system as disclosed herein may be flexible. In some applications where flexibility is required, it may be preferred that Barrier layer 1 has some organic component. One such example system is the hybrid barrier layer taught in U.S. Pat. No. 7,968,146, the disclosure of which is incorporated by reference in its entirety. This material is a hybrid of inorganic SiO₂ and polymeric silicone. Thus, in an embodiment, Barrier layer 1 may include primarily, exclusively, or essentially mixture of polymeric silicon and inorganic silicon. As previously described, for such a barrier layer the weight ratio of polymeric silicon to inorganic silicon may be in the range of 95:5 to 5:95, and the polymeric silicon and the inorganic silicon may be created from the same source of precursor material. At room temperature, a layer of this hybrid material is free of microcracks when deposited approximately thicker than 100 nm. Such a layer can be grown relatively thick to satisfy the particle coverage property without compromising on flexibility. The thickness of Barrier layer 2 then may be chosen to meet flexibility requirements. The morphology, adhesion strength, and built-in stress of Barrier layer 2 (polycrystalline or amorphous), of barrier layer 2 may influence the overall flexibility.

In embodiments as disclosed above, a permeation barrier system may include multiple barrier layers. A first barrier layer may provide coverage of particles on the surface, and provide the required edge seal with relatively small bezel width. A second barrier layer may have a relatively ultralow permeability to moisture, and may provide protection in the vertical direction. In general, the thickness of the first barrier layer may be substantially larger than the second.

In an embodiment, techniques for fabrication of a permeation barrier system as disclosed herein are provided. Referring to FIG. 4, an environmentally sensitive device such as an OLED may be placed on a substrate by deposition, such as vacuum deposition, or other fabrication technique. Barrier layer 1 may be directly disposed over the OLED. The footprint of Barrier layer 1 may extend beyond the edge of the OLED by a bezel width w. The bezel width w may range between 1 μm to 50,000 μm. A second barrier layer. Barrier layer 2, may then be disposed over Barrier layer 1.

In an embodiment, Barrier layers 1 and 2 may be deposited through a single common mask, or through masks having the same opening size and arrangements.

In an embodiment, two barrier layers may be deposited on a flexible substrate before deposition of the electronic device, and two barrier layers deposited after deposition of the electronic device on top of the first pair of barrier layers. The first pair of barrier layers may be deposited such that the Barrier layer 2 material, i.e., the low permeability material, is deposited first, and Barrier layer 1 (the higher permeability layer) is deposited on top of the Barrier layer 2 layer. After deposition of the device the barrier layers may be deposited as previously disclosed, i.e., with Barrier layer 1 being followed by Barrier layer 2.

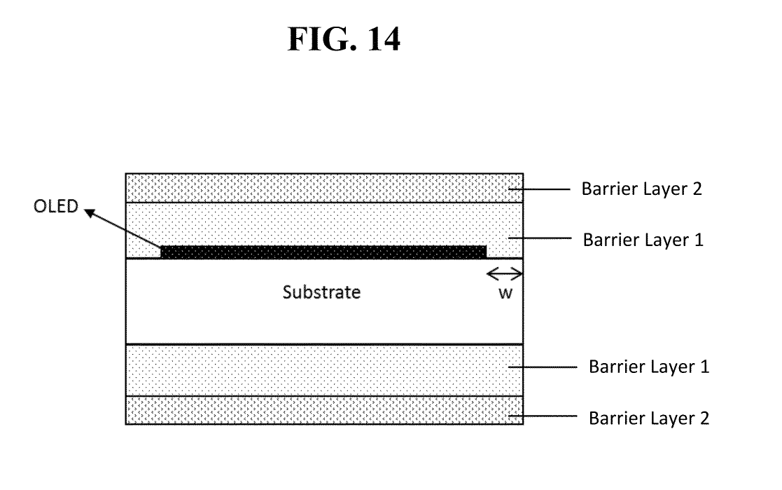

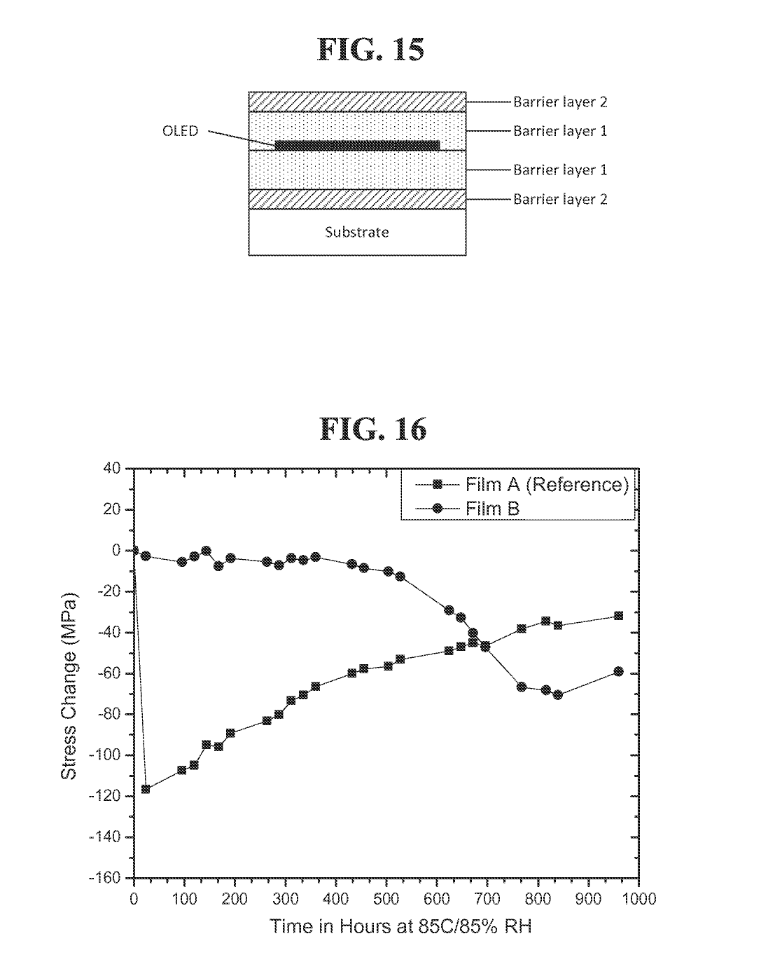

If polymeric substrates such as PET, PEN and the like are used, the schematic structures shown in FIG. 14 and FIG. 15 may be adopted to provide adequate moisture protection. In FIG. 14, the backside of the polymeric substrate may be coated with the permeation barrier system. In FIG. 15, the substrate may coated with the permeation barrier system prior to OLED growth.

Barrier layers 1 and 2 may be fabricated, for example, via a vacuum deposition. Vacuum deposition techniques may include, but are not limited to sputtering, chemical vapor deposition (CVD), evaporation, sublimation, atomic layer deposition (ALD), plasma enhanced chemical vapor deposition (PECVD), plasma assisted atomic layer deposition, and combinations thereof. The footprint of Barrier layer 2 may be preferably the same as Barrier layer 1, but may be larger or smaller. Plasma or ALD processes may be preferred over evaporation process for Barrier layer 1 to obtain desirable barrier properties and particle coverage.

Barrier layers 1 and 2 may be made from a single material or different materials. In addition, each of the barrier layers themselves can made from a single material or different materials. For example, if the materials are deposited by sputtering, sputtering targets of different compositions can be used to obtain this layer. Alternatively, two targets of same composition can be used with different reactive targets. Two different types of deposition sources may be used.

Each of Barrier layers 1 and 2 may be amorphous or polycrystalline. For example, thin films of indium zinc oxide deposited by reactive sputtering from an indium zinc oxide target with oxygen reactive gas are typically amorphous. Thin films of Aluminum oxide deposited by reactive sputtering from an aluminum target with oxygen reactive gas are typically polycrystalline. Nanolaminates consisting of alternate thin stacks of zinc oxide and aluminum oxide can also be used for barrier layers. For example, if the thin films are deposited by atomic layer deposition, alternate thin stacks of ZnO/Al₂O₃ may be used.

Barrier layers 1 and 2 can be transparent or opaque depending on the design and application of the display device. Preferred barrier materials include, but are not limited to metals, metal oxides, metal nitrides, metal oxynitrides, metal carbides, metal oxyborides and combinations thereof. Metals are preferably selected from aluminum, chromium, titanium, gold, germanium, molybdenum, copper, indium, zinc, tin, nickel, tungsten, iridium, platinum and combinations thereof. Metal oxides are preferably selected from silicon oxide, aluminum oxide, indium oxide, tin oxide, zinc oxide, indium tin oxide, indium zinc oxide, aluminum zinc oxide, tantalum oxide, zirconium oxide, niobium oxide, molybdenum oxide and combinations thereof. Metal nitrides are preferably selected from silicon nitride, aluminum nitride, boron nitride and combinations thereof. Metal oxynitrides are preferably selected from aluminum oxynitride, silicon oxynitride, boron oxynitride and combinations thereof. Metal carbides are preferably selected from tungsten carbide, boron carbide, silicon carbide and combinations thereof. Metal oxyborides are preferably zirconium oxyboride, titanium oxyboride and combinations thereof. For Barrier layer 1, some organic content maybe preferred to ensure that a thick layer can be made without cracking or delamination due to defects or internal stress. This organic content may also improve the flexibility of the film. One such example is the hybrid barrier layer taught in U.S. Pat. No. 7,968,146, the disclosure of which is incorporated by reference in its entirety.

Notably, techniques for depositing a permeation barrier system as disclosed herein may be performed at temperatures lower than the glass transition temperature of organic materials used in the associated OLEDs. Further, because it is possible to fabricate a permeation barrier system as disclosed herein using two all-vacuum steps, transfer times and masking times may be significantly minimized when compared to other barrier technology techniques. The permeation barrier property of Barrier layer 1 also man be tuned over a wide range to meet a desired performance standard, as previously described. This provides a wide process window for deposition, and means that a minor process drift during deposition of Barrier layer 1 will not affect the final performance drastically.

In an embodiment, a technique for fabricating a permeation barrier system as disclosed herein may include choosing a thickness of Barrier layer 1 based on the largest particle to be covered, as previously described. For example, it may be desirable for the barrier film thickness to be at least half the expected covered particle diameter to completely encapsulate the particle. The bezel width may be determined by the permeability of Barrier layer 1 P1. If the diffusion coefficient D1, solubility S1 and thickness of Barrier layer 1 are known, the minimum required bezel width can be calculated as shown in FIG. 10. Conversely, if the bezel width is specified for a particular application, the minimum required D1 may be calculated. Subsequently, a material and thickness of Barrier layer 2 may be chosen to meet the permeability requirement, as previously described.

### EXPERIMENTAL

The performance of a permeation barrier system as disclosed herein was verified. In all experiments, Barrier layer 1 is a hybrid barrier layer grown by plasma enhanced chemical vapor deposition (PECVD) of an organic precursor with a reactive gas such as oxygen. e.g., HMDSO/O₂. Barrier layer 2 is an amorphous inorganic layer of Indium Zinc Oxide (IZO). IZO was deposited by reactive DC magnetron sputtering from an IZO target with oxygen as the reactive gas.

(1) Stress change test: Two 2″ Si wafers were used as substrates. On one wafer, a 1 μm thick barrier layer 1 (Film A) was deposited by PECVD. On the other wafer, a permeation barrier system as disclosed herein, which included Barrier layer 1 and Barrier layer 2, was deposited. Barrier layer 1 is a 1 um thick hybrid barrier deposited by PECVD (similar to film A). Barrier layer 2 is 500 A of IZO deposited by DC reactive magnetron sputtering from an IZO target with oxygen as the reactive gas. This two layer barrier film is Film B. The average stress of these samples was monitored at 85 C, 85% relative humidity (RH) over time. When the hybrid barrier film is exposed to water, H₂O diffuses into the film causing it to expand. When deposited on a silicon wafer, the barrier film tends to expand, resulting in an increase in compressive stress. The change in stress is related to the concentration of dissolved water in the barrier.

FIG. 16 shows a plot of the stress change (in MPa) vs. time (hours) at 85 C, 85% RH. It was found that the stress of Film A (Reference) rapidly changes by −118 MPa (compressive) within 24 hours in 85 C, 85% RH. On the other hand, stress of the Film B changes negligibly in 24 hours. Further, the stress changes to its maximum value of −70 MPa (compressive) after 775 hours. As mentioned before, in a permeation barrier system as disclosed herein, because Barrier layer 2 is disposed over Barrier layer 1, Barrier layer 1 is not directly exposed to water vapor. Ideally, moisture will have to diffuse through the bulk of Barrier layer 2 before it reaches the Barrier layer 1/Barrier layer 2 interface. Since Barrier layer 2 has ultralow permeability, a large delay time is introduced and the stress change is kept within critical bounds thereby delaying delamination of the device due to high stress. This plot suggests that barrier layer 2 provides ultralow permeability to moisture and oxygen and minimizes the stress change of barrier layer 1 and thereby overall stress.

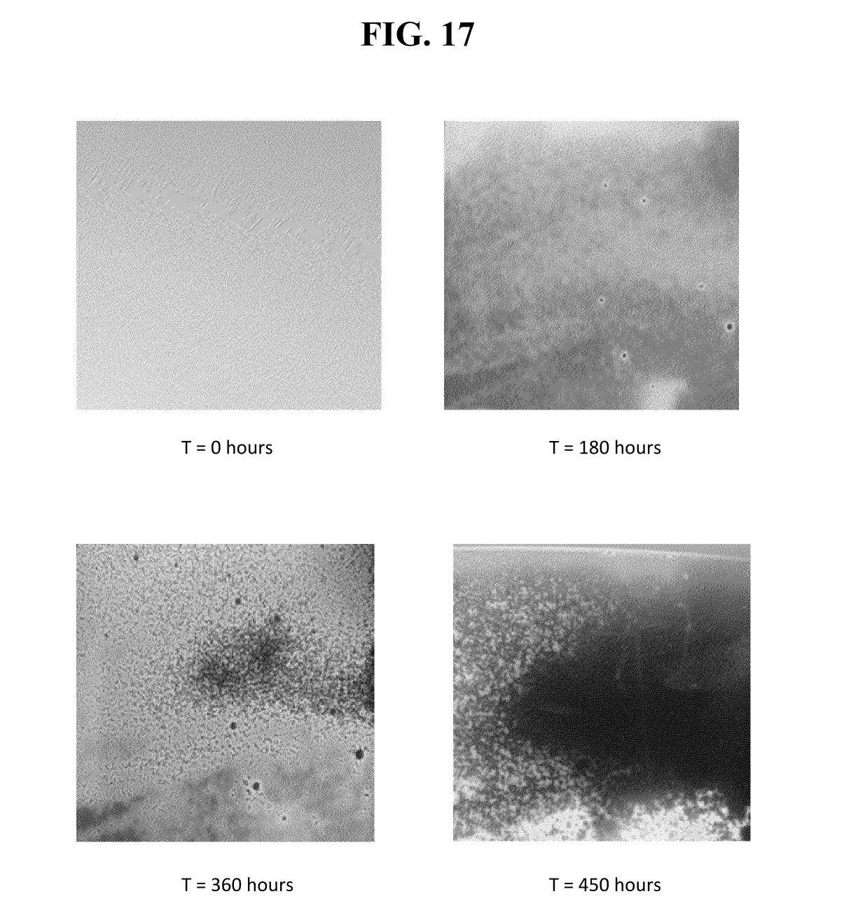

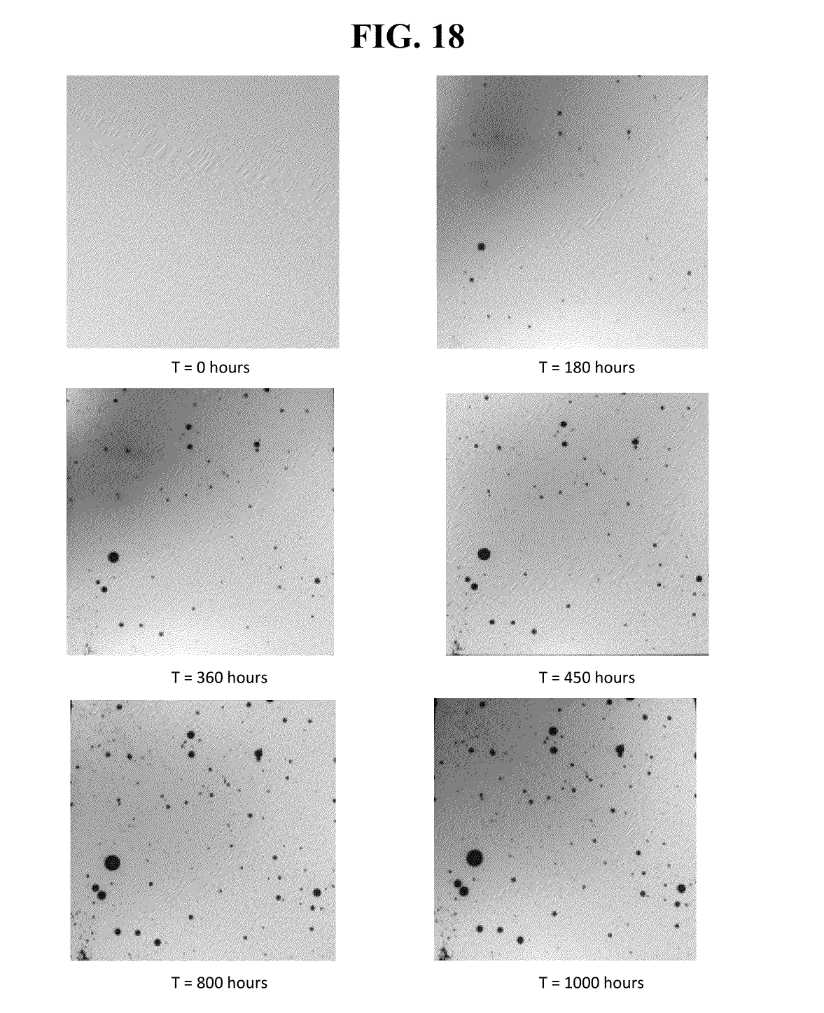

(2) Moisture Permeability Test (Encapsulation of OLED): Two transparent OLEDs were grown on glass substrates. Device 1 was encapsulated with a 9 micron thick single Barrier layer 1 deposited by PECVD. Device 2 was encapsulated with a permeation barrier system as disclosed, which includes Barrier layer 1 and Barrier layer 2. In this system, Barrier layer 1 is the same 9 micron thick barrier deposited by PECVD on device 1. Barrier layer 2 is 500 A of IZO deposited by DC reactive magnetron sputtering from an IZO target. The devices were monitored at 85 C, 85% relative humidity (RH) over time. FIG. 17 shows photographs of the OLED Device 1 pixel at T=0 hours, T=180 hours, T=360 hours and T=450 hours respectively. At T=0 hours, the pixel is defect free and lights up uniformly. At T=450 hours the barrier delaminates due to change in stress at 85 C/85% RH and the dark spots spread. The device does not light up after 450 hours. FIG. 18 shows photographs of the OLED Device 2 pixel at T=0 hours, T=180 hours, T=360 hours, T=450 hours, T=800 hours and T=1000 hours respectively. At T=0 hours, the pixel is defect free and lights up uniformly. At T=450 hours, T=800 hours, T=1000 hours very few dark spots are observed, but the permeation barrier system stays intact. These dark spots may be attributed to particles >4.5 μm that have not been fully covered by the barrier system, which may be weak spots for moisture ingression. However, no delamination is observed and the pixel still turns on.

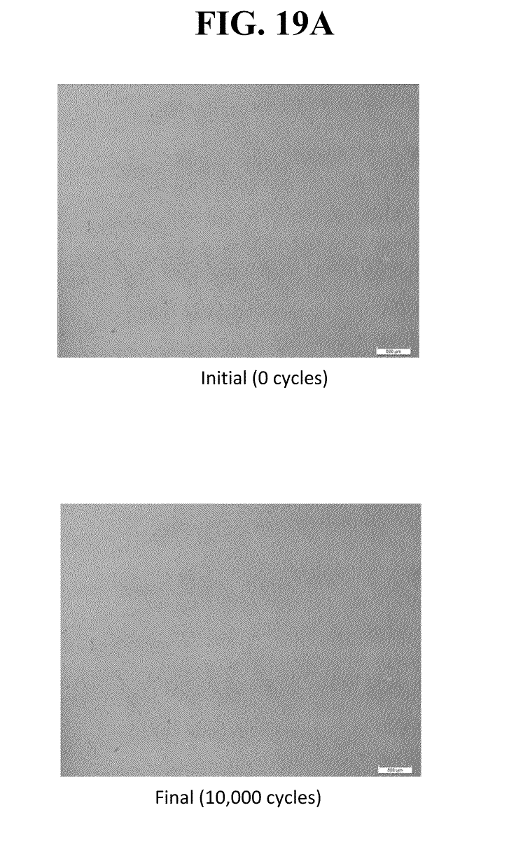

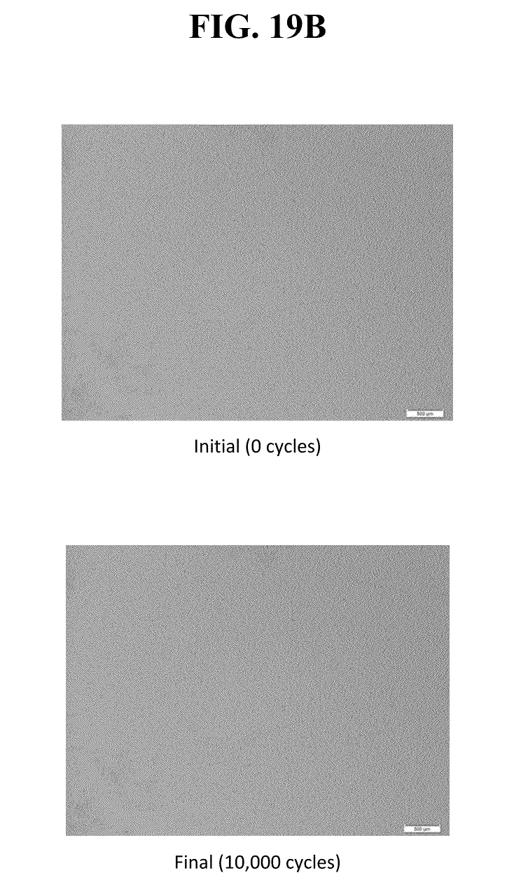

(3) Flexibility Test: In this test, 2″×3″ of a 50 μm thick Kapton sheet was coated with a permeation barrier system as disclosed herein, which includes Barrier layer 1 and Barrier layer 2. In this system, Barrier layer 1 is a 2 μm thick hybrid barrier deposited by PECVD. Barrier layer 2 is IZO deposited by DC reactive magnetron sputtering from an IZO target with oxygen gas. IZO forms a smooth amorphous thin film devoid of any grain boundaries and cracks. For the flexibility test, the thickness of IZO was varied from a) 50 nm b) 100 nm, and the flexibility was tested by rolling over 0.5-inch radius for 10,000 cycles. FIGS. 19 A and 19B show the microscopic images of the surface before and after 10,000 cycles of flex test for 50 nm and 100 nm, respectively. As seen from the figures, no cracks are observed after the flexibility test.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

We claim:

1. A permeation barrier comprising:
a first barrier layer having a first water vapor permeability of not more than 10⁻⁵ g/(cm sec) at 85 C, 85% relative humidity (RH) and a first thickness of at least 250 nm; and
a second barrier layer disposed over the first barrier layer, the second barrier layer having a second water vapor permeability and a second thickness;
wherein the first water vapor permeability is higher than the second water vapor permeability.

2. The permeation barrier of claim 1, wherein the first thickness is greater than the second thickness.

3. The permeation barrier of claim 2, wherein the first thickness is at least 5 times the second thickness.

4. The permeation barrier of claim 2, wherein the first thickness is at least 10 times the second thickness.

5. The permeation barrier of claim 4, wherein the first thickness is 10-10⁴ times the second thickness.

6. The permeation barrier of claim 1, wherein the first barrier layer is flexible.

7. The permeation barrier of claim 1, wherein the second barrier layer is flexible.

8. The permeation barrier of claim 1, wherein the first water vapor permeability is greater than the second water vapor permeability.

9. The permeation barrier of claim 8, wherein the first water vapor permeability is at least 10 times the second water vapor permeability.

10. The permeation barrier of claim 9, wherein the first water vapor permeability is 10²-10⁸ times the second water vapor permeability.

11. The permeation barrier of claim 1, wherein the first water vapor permeability is less than 1.3×10⁻¹¹ g/(cm·sec) at 85 C, 85% RH.

12. The permeation barrier of claim 1, wherein the first water vapor permeability is less than 3.4×10⁻¹⁴ g/(cm·sec) at 85 C, 85% RH.

13. The permeation barrier of claim 1, wherein at least one of the first barrier layer and the second barrier layer comprises a material selected from the group consisting of: aluminum, chromium, titanium, gold, germanium, molybdenum, copper, indium, zinc, tin, nickel, tungsten, iridium, platinum and combinations thereof.

14. The permeation barrier of claim 1, wherein at least one of the first barrier layer and the second barrier layer comprises a material selected from the group consisting of: silicon oxide, aluminum oxide, zinc oxide, indium oxide, tin oxide, zinc oxide, indium tin oxide, indium zinc oxide, aluminum zinc oxide, tantalum oxide, zirconium oxide, niobium oxide, molybdenum oxide and combinations thereof.

15. The permeation barrier layer of claim 1, wherein at least one of the first barrier layer and the second barrier layer is selected from the group consisting of: silicon nitride, aluminum nitride, boron nitride and combinations thereof.

16. The permeation barrier layer of claim 1, wherein at least one of the first barrier layer and the second barrier layer is selected from the group consisting of: aluminum oxynitride, silicon oxynitride, boron oxynitride, and combinations thereof.

17. The permeation barrier layer of claim 1, wherein at least one of the first barrier layer and the second barrier layer is selected from the group consisting of: tungsten carbide, boron carbide, silicon carbide, and combinations thereof.

18. The permeation barrier layer of claim 1, wherein the first barrier layer consists essentially of a mixture of polymeric silicon and inorganic silicon

19. The permeation barrier layer of claim 18, wherein the weight ratio of polymeric silicon to inorganic silicon is in the range of 95:5 to 5:95

20. The permeation barrier layer of claim 18, wherein the polymeric silicon and the inorganic silicon are created from the same source of precursor material.

21. The permeation barrier layer of claim 1, wherein at least one of the first barrier layer and the second barrier layer is selected from the group consisting of: zirconium oxyboride, titanium oxyboride, and combinations thereof.

22. A device comprising a permeation barrier as recited in claim 1.

23. The device of claim 22, wherein the device has a bezel width of not more than 5 mm.

24. A method of encapsulating an electronic device, the method comprising:
depositing a first barrier layer having a first water vapor permeability of not more than 10⁻⁵ g/(cm sec) at 85 C, 85% RH and a first thickness of at least 250 nm over the electronic device; and
depositing a second barrier layer over the first barrier layer, the second barrier layer having a second water vapor permeability and a second thickness;
wherein the first water vapor permeability is higher than the second water vapor permeability.

25. The method of claim 24, wherein the first thickness is larger than the second thickness, and the first barrier layer is deposited at a faster rate than the second barrier layer.

26. The method of claim 24, wherein the first thickness is smaller than the second thickness, and the first barrier layer is deposited at a faster rate than the second barrier layer.

27. The method of claim 24, wherein the first barrier layer is deposited through a mask and the second barrier layer is deposited through the same mask as the first barrier layer.

28. The method of claim 24, further comprising:
depositing a third barrier layer;
depositing a fourth barrier layer over the third barrier layer; and
disposing the electronic device over the third barrier layer and the fourth barrier layer;
wherein the fourth barrier layer has a higher water vapor permeability than the third barrier layer; and
wherein the fourth barrier layer has a greater thickness than the third barrier layer.
